(19) United States
(12) Patent Application Publication
(10) Pub. No.: US 2011/0220171 A1
(43) Pub. Date: Sep. 15, 2011

(54) Photovoltaic Structure and Solar Cell and Method of Fabrication Employing Hidden Electrode

(76) Inventors: Sagi V. Mathai, Palo Alto, CA (US); Shih-Yuan Wang, Palo Alto, CA (US)

(21) Appl. No.: 13/130,814

(22) PCT Filed: Jan. 30, 2009
(86) PCT No.: PCT/US2009/032729

§ 371 Date: May 24, 2011

(51) Int. Cl. H01L 31/0352; H01L 31/18; H01L 31/042; B82Y 99/00

(52) U.S. Cl. 136/244; 438/66; 136/255; 977/762; 977/948

(57) ABSTRACT

A photovoltaic structure (100), a solar cell (100, 200) and a method (300) of fabricating a solar cell (100, 200) employ a hidden electrode (122, 222, 422) on a formed (320) mesa (120, 220, 420) and a bramble (130, 230, 430) of grown (330) nanowires. The mesa includes an insulator island (121, 221, 421) adjacent to a surface of the substrate (110, 210, 410) and the hidden electrode buried under a seed layer on the insulator island. One end of some of the nanowires (134, 234) is anchored to the seed layer (124, 224, 424) of the mesa. One end of others of the nanowires (132, 232) is anchored to a seed layer (114, 214, 414) formed (310) on the substrate adjacent to the mesa. The seed layers independently are an extrinsic semiconductor. A semiconductor junction includes the seed layers and some of the nanowires of the bramble.

### CROSS-REFERENCE TO RELATED APPLICATIONS

N/A

### STATEMENT REGARDING FEDERALLY SPONSORED RESEARCH OR DEVELOPMENT

N/A

### BACKGROUND

Photonic devices, such as photovoltaic cells, are the subject of much interest due to high energy costs and U.S. dependence on fossil fuel from foreign sources. The efficiency and quality of photovoltaic cells have improved, significantly over the last 10 years. Efforts to lower the cost of photovoltaic cells have been directed at alternative materials and manufacturing methods.

Historically, high performance semiconductor devices, especially those with p-n junctions, comprise single crystals of one or more semiconductor materials. Among other things, using such single crystal materials for semiconductor devices essentially eliminates the scattering of charged carriers (e.g., holes and electrons) at grain boundaries that exist in non-single crystal semiconductor materials such as poly-crystalline semiconductor materials. Such scattering adversely reduces the drift mobility and the diffusion of charged carriers, and leads to a degraded performance (e.g., increased resistance and decrease in optical to electrical conversion efficiency) of devices, such as transistors and solar cells. Even when different semiconductor materials were employed together in a single device, such as in a heterostructure or heterojunction device, single crystal semiconductor materials are generally chosen based on their respective lattice structures to insure that the structure realized is an essentially single crystal structure as a whole. Similarly, nanostructures including, but not limited to, nanowires and nanodots are typically nucleated and grown from single crystal substrates, in part to capitalize on the uniform nature of the lattice of such substrates that provides required crystallographic information for the nanostructures to be grown as single crystals.

Relatively recently, amorphous and other non-single crystal semiconductor materials have begun to attract attention, in particular, in solar cell applications, at least for potential cost savings. While having the disadvantages associated with multiple grain boundaries, such non-single crystal semiconductor materials can be considerably cheaper to manufacture than their single crystal counterparts. In many applications, the lower cost of producing the semiconductor device from non-single crystal materials outweighs any loss of performance that may result. Furthermore, using non-single crystal semiconductor materials for heterostructures can increase the possible combinations of materials that can be used since lattice mismatch is less of a concern with non-single crystal semiconductors.

While significant progress has been made in overcoming many of the practical challenges associated with producing high performance, lower cost solar cells, the manufacturing cost and the material costs of such photovoltaic devices are still too high, especially to make solar cells more affordable and attractive to the average consumer and industry as a whole.

### BRIEF DESCRIPTION OF THE DRAWINGS

Some features of various embodiments of the present invention may be more readily understood with reference to the following detailed description taken in conjunction with the accompanying drawings, where like reference numerals designate like structural elements, and in which:

FIG. 1 illustrates a cross sectional view of a photovoltaic structure, according to an embodiment of the present invention.

FIG. 2 illustrates a cross sectional view of a solar cell, according to an embodiment of the present invention.

FIG. 3 illustrates a flow chart of a method of fabricating a solar cell, according to an embodiment of the present invention.

FIG. 4A-4F illustrate cross sectional views of a solar cell being fabricated in accordance with the method illustrated in FIG. 3, according to an embodiment of the present invention.

### DETAILED DESCRIPTION

Embodiments of the present invention provide a photovoltaic structure, a solar cell and a method of fabrication that employ a bramble of nanowires and hidden electrodes. In particular, the electrodes are buried beneath respective seed layers that support the bramble of nanowires and as such, beneath a semiconductor junction of the photovoltaic structure of the solar cell. The hidden electrodes do not obstruct a photon path to the semiconductor junction for example, by shadowing the photon path or reflecting the photons. Yet the hidden electrodes are readily accessible external to the solar cell. The bramble of nanowires is antireflective and facilitates light absorption by the solar cell. The nanowires of the bramble provide greater surface area along their length to absorb a photon as a part of the semiconductor junction in the solar cell. The large surface area provided by the bramble of nanowires facilitates an efficiency of the photovoltaic structure for solar cell and photodiode applications.

The photovoltaic structure embodiments of the present invention include a mesa on a substrate; the mesa includes an insulator island adjacent to the substrate and an electrode buried under a seed layer on the insulator island. The substrate includes another electrode covered with another seed layer. In some embodiments, the substrate is electrically conductive and functions as the other electrode. In these embodiments, the substrate seed layer covers the substrate surface and therefore, covers the electrode. In other embodiments, the substrate further includes an electrode layer buried between the substrate seed layer and the substrate. In these other embodiments, the substrate may be electrically conductive or nonconductive. The photovoltaic structure embodiments further include a bramble of nanowires that populates both of the seed layers. Some of the nanowires of the bramble extend from and are connected to the seed layer on the substrate. Others of the nanowires extend from and are connected to the seed layer on the respective mesa. Nanowires of the bramble that populate the seed layer on the substrate are adjacent to and substantially surround the mesa in a disordered array. Nanowires of the bramble that populate the seed layer on the mesa extend from the top and the sides of the mesa in a disordered array. The seed layers and the nanowires from the bramble form semiconductor junctions of the photovoltaic structure.

The seed layers independently comprise an extrinsic semiconductor. The nanowires comprise one or both of an intrinsic semiconductor and an extrinsic semiconductor in axial segments along the length of the nanowires. A semiconductor junction is formed, for example, by a nanowire from the substrate physically contacting a nanowire from the mesa. In another example, a semiconductor junction is formed by a nanowire of the substrate physically contacting the mesa seed layer. In another example, a semiconductor junction is formed by a nanowire of the mesa physically contacting the substrate seed layer. In some embodiments, the physically contacting nanowires are fused together. In some embodiments, the nanowire that extends from one seed layer to physically contact the other seed layer is fused to the other seed layer. The photovoltaic structure may be used in a number of applications including, but not limited to, solar cell applications and photodiode applications. In some embodiments, the photovoltaic structure is a solar cell. In other embodiments, the photovoltaic structure is a photodiode.

The solar cell embodiments of the present invention include a plurality of the above-described mesas spaced apart on a substrate and further include the bramble of nanowires. The substrate includes a seed layer that covers an electrode layer on the substrate. In some embodiments, the electrode layer is the substrate when the substrate is electrically conductive. The bramble of nanowires populates the seed layers on the plurality of mesas and populates the seed layer of the substrate in a disordered array. The nanowires that extend from and are connected to the seed layer on the substrate are located in gaps between the spaced apart mesas. The nanowires that extend from and are connected to the seed layers on the plurality of mesas extend from the top and the sides of the respective mesa. Some nanowires of the bramble together with the respective seed layers form semiconductor junctions of the solar cell in much the same ways as described above for the photovoltaic structure. The substrate electrode of the solar cell embodiments is shared among the plurality of mesas and provides a common access to the plurality of mesas from one end of the semiconductor junctions, while the electrode of each mesa of the plurality provides access to the individual mesas from an opposite end of the semiconductor junctions. The electrodes on the respective mesas of the plurality are effectively hidden so not to obstruct the photon path of the solar cell. In some embodiments, the solar cell is a plurality of interconnected ones of the photovoltaic structures, described above.

The method of fabrication embodiments of the present invention create a buried electrode on a mesa that is on and electrically isolated from a buried substrate electrode of a photovoltaic structure or a solar cell. The mesas are formed using one or more of a variety of techniques including, but not limited to, one or more of photolithography, nanoimprint lithography (NIL), stamping, wet etching and dry etching. Moreover, depending on the materials used for the substrate, the method of fabrication may include a roll-to-roll process to form a plurality of photovoltaic mesas on a solar cell fabricated using batch processing, for example. In some embodiments, the fabrication process is a relatively low temperature process, for example, below 400° C., which allows for a greater variety of materials to be used.

The bramble of nanowires is grown in accordance with the method embodiments from the separate seed layers on the respective buried electrodes. Some of the nanowires are grown electrically connected at one end to the buried substrate electrode via the substrate seed layer (i.e., a first electrode via a first seed layer on the substrate) and others of the nanowires are grown electrically connected at one end to the buried mesa electrode via the mesa seed layer (i.e., a second electrode via a second seed layer that is on each mesa) using a catalyzed growth process. The seed layers are non-single crystal semiconductor materials. Moreover, a substrate or support for the solar cell or the photovoltaic structure is a non-single crystal material. Non-single crystal materials not only may reduce cost of the solar cell and the photovoltaic structure, but also provide for a greater variety of materials to be used as well. Moreover, certain non-single crystal materials facilitate in providing the bramble of nanowires, as described further below.

A “nanowire” is an individual quasi-one dimensional, nano-scale structure characterized as having two spatial dimensions or directions that are much less than a third spatial dimension or direction (i.e., length dimension). The presence of the third, greater dimension in nanowires facilitates electron wave functions along that dimension while conduction is quantized in the other two spatial dimensions. As used herein, the term ‘nanowire’ is defined as a single-crystal semiconductor nano-scale structure, as described above, having an axial length (as a major or third spatial dimension), opposite ends and a solid core. Moreover, the nanowire may have a width dimension from tens of nanometers to several hundred nanometers, for example; an axial length from a micron to several microns, for example; and the nanowire may not have the same width dimension along the axial length of the nanowire, for example. As such, the nanowire may have a tapered shape or a non-tapered shape and such shape may be uniform or non-uniform along the axial length of the nanowire.

A ‘bramble’ of nanowires is defined as a plurality of nanowires that have a disordered or chaotic arrangement with respect to one another and with respect to the surface from which the nanowires are anchored. The nanowires are attached at one end to a seed layer of a non-single crystal material comprising crystallites. The nanowires extend from the seed layer in a variety of directions, wherein some nanowires physically contact other nanowires and some nanowires fuse together during growth. As such, the nanowires of the bramble may be considered to be ‘tangled’. Effectively, the disordered arrangement of the nanowires in the bramble increase the probability that photons will interact with and be absorbed by the nanowires rather than be lost (e.g., reflected) to the surroundings. As such, the bramble of nanowires provides light absorbing and trapping ability. The disordered arrangement of the nanowires of the bramble is dictated by lattice orientations of the crystallites having a disordered arrangement with respect to one another in the seed layer. Further, the ‘bramble of nanowires’ has a non-uniform distribution of angular orientations of the nanowires. The non-uniform distribution of angular orientations is related to the disorder of the lattice orientations of the crystallites in the seed layer to which the nanowires of the bramble are coherently attached (i.e., ‘integral to’ or ‘anchored to’, as used herein). In other words, there is no predetermined order and no resulting order to the angular orientations of the nanowires in the bramble.

In contrast, nanowires grow in an ordered array on a single crystal material layer or on a layer of uniform nanocrystals or nanoparticles (e.g., having predominantly substantially perpendicular nanowires). The ordered array of nanowires is manifested as most of the nanowires growing in a primary direction. The nanowires that grow on a single crystal material layer or a layer of nanocrystals or nanoparticles are substantially uniformly oriented with the uniform crystal lattice orientation of the single crystals (e.g., uniformly substantially perpendicular to a [111] lattice direction). Therefore, the angular orientations of nanowires integral to a single crystal material layer or a layer of nanocrystals or nanoparticles have a negligible distribution of angular orientations relative to the non-uniform distribution of angular orientations of the nanowires integral to a non-single crystal seed layer according to the various embodiments of the present invention.

Herein, a ‘seed layer’ is defined as a non-single crystal semiconductor material that has a microstructure with short range atomic ordering. In contrast, a ‘single crystal’ material has a crystal lattice microstructure with long-range atomic ordering that is continuous in micrometer scale. The short range atomic ordering of the seed layer manifests as multiple, small regions of crystalline material or ‘crystallites’ dispersed within and generally throughout the seed layer. A crystallite provides a template for potential nucleation and growth of a single crystal nanowire. The regions of crystallites in the seed layer may range from clusters of individual crystallites to discrete individual crystallites. Thus, by definition, the ‘seed layer’ comprises multiple crystallites buried in an amorphous matrix. Adjacent crystallites within the seed layer have respective lattices that are non-uniformly oriented with respect to one another. Further, crystallites adjacent to a surface of the seed layer are non-uniformly located across the surface. The crystallites of the seed layer provide crystallographic information to a nanowire during catalyzed nanowire growth.

As used herein, the term ‘crystallite’ means a range of crystallites from a single crystallite to a group of crystallites aggregated together for the purposes of some embodiments. Specifically, a crystallite provides a nucleation site for epitaxial growth of a single crystal nanowire from the seed layer during fabrication of the photovoltaic structure and the solar cell. As such, the nanowires are said to be ‘integral to’ or ‘anchored to’ a crystallite of the seed layer during the nanowire growth. The grown nanowire forms an interface (e.g., a homojunction or a heterojunction) with the crystallite where the nanowire is connected to the crystallite commensurately. In some embodiments, the crystal lattice of the single crystal nanowire and the crystal lattice of the crystallite of the seed layer are coherent. The integral crystal-structure connection at the interface between the seed layer and the single crystal nanowire facilitates using the interface in semiconductor junction-related photovoltaic applications. The coherent lattices of the seed layer and the single crystal nanowire facilitate charge carrier transport through the interface, for example. A width of the nanowire may be one of larger than, smaller than and the same size as the crystallite to which the nanowire is integrally attached. Where multiple crystallites are involved, the nanowire width may be one of larger than, smaller than and the same size as a length scale of the multiple crystallites over which the nanowire nucleates on the surface.

A ‘non-single crystal material’ is defined as a material having a structure that is not a single crystal structure. A non-single crystal structure includes one of a relatively unidentifiable or no crystallographic structure (e.g., glass), a microcrystalline structure (i.e., having short range atomic order, as defined herein, that includes amorphous semiconductors), and a polycrystalline structure (i.e., having short range atomic order of relatively greater extent than a microcrystalline structure). In contrast, the single crystal structure has relatively long range atomic order. A non-single crystal material includes, but is not limited to, a semiconductor material, a dielectric or an insulator material and a metal. A ‘microcrystalline semiconductor’ material is one type of a non-single crystal semiconductor material that has a microstructure with short range atomic ordering. Another non-single crystal semiconductor material is an ‘amorphous semiconductor’ material. The crystallites in the respective non-single crystal semiconductor materials define the short range atomic ordering of the material.

For example, silicon (Si) may be deposited on a non-single crystal substrate as a microcrystalline silicon layer or an amorphous silicon layer, depending on the deposition conditions. By definition, each of such ‘microcrystalline semiconductor’ material and ‘amorphous semiconductor’ material has available crystallites to facilitate nucleation of single crystal nanowires and are examples of the materials of the respective seed layers according to various embodiments of the invention. Reference herein to a ‘microcrystalline semiconductor material’ includes within its scope an ‘amorphous semiconductor material’, unless a distinction is necessary.

In some embodiments, the seed layers are independently a microcrystalline semiconductor material and the substrate may be either a single crystal material or a non-single crystal material. Using a non-single crystal material as a substrate and a non-single crystal semiconductor seed layer, according to some embodiments of the present invention, may provide cost and manufacturing advantages as well as performance advantages to the solar cell. For example, a solar cell that can be manufactured using non-single crystal materials (e.g., a glass substrate with microcrystalline seed layers) interfaced to single crystal nanowires may be one or both of cost-effective to make and efficient. This may be so simply due to the fact that a greater variety of materials would be available for the solar cell. Moreover, the greater variety of these available materials may provide for energy conversion from more of the solar spectrum than previously available, which may improve solar cell efficiency according to some embodiments.

The term ‘extrinsic semiconductor’ is defined as a semiconductor material that is intentionally doped with either a p-type dopant or an n-type dopant to provide a higher level of electrical conductivity to the semiconductor material than the semiconductor inherently has. The term ‘extrinsic region’ is a region of the extrinsic semiconductor. The term ‘intrinsic semiconductor’ is defined as a semiconductor material that is one of undoped, lightly doped, and not intentionally doped with a dopant material. The term ‘intrinsic region’ is a region of the intrinsic semiconductor. By ‘lightly doped’ and ‘not intentionally doped’ (or ‘unintentionally doped’), it is meant that a relatively small amount of dopant may be incorporated in the intrinsic semiconductor, for example as a result of doping an extrinsic semiconductor. The relatively small amount of dopant is a very low concentration of dopant, for example approximately 10¹⁵ per cubic centimeter, relative to an extrinsically doped semiconductor, which may have 10¹⁷ per cubic centimeter of dopant or higher, for example.

The term ‘semiconductor junction’ includes within its scope, a p-n junction, a p-i-n junction and a Schottky junction. For example, a Schottky junction may be formed between a respective metal electrode and a respective semiconductor seed layer. A p-n junction may be formed between a nanowire and a respective seed layer to which the nanowire is anchored when the nanowire is an extrinsic semiconductor doped with one of an n-type dopant and a p-type dopant and the respective seed layer is an extrinsic semiconductor doped with the other one of the dopant types, for example. A p-i-n junction may be formed between nanowires and the seed layers. For example, a nanowire from the solar cell substrate seed layer that physically contacts a nanowire from the mesa seed layer may form a p-i-n junction when the nanowires comprise an intrinsic semiconductor and the respective seed layers to are reversely doped extrinsic semiconductors. The physically contacting nanowires form an i-region between a p-region and an n-region, for example, of the p-i-n junction.

Moreover, the level of doping in the seed layers and within the bramble of nanowires may be the same or different. The variation in dopant level may yield a dopant gradient, for example. In an example of differential doping, a respective seed layer may be heavily doped to yield a p+ region and the other seed layer may be heavily doped to yield an n+ region, both of which provide a low resistivity within the respective seed layers; while an adjacent axial length segment of the nanowires anchored to the respective seed layers may be less heavily p-doped or n-doped to yield a p region and an n-region. In this example, the remainder of axial length or volume of the respective nanowires may be intrinsic to form an i-region, for example.

According to some embodiments, the solar cell and the photovoltaic structure independently may comprise a heterostructure or a heterojunction. For example, semiconductor materials having differing band gaps are employed to respectively realize the single crystal nanowires and the seed layers. The photovoltaic structure or the solar cell that comprises such differing materials is termed a ‘heterostructure’ photovoltaic cell. Further, according to various embodiments, the photovoltaic structure and the solar cell independently are ‘hetero-crystalline’ photovoltaic cells. The term ‘hetero-crystalline’ is defined herein as a structure comprising at least two different types of structural phases. For example, a photovoltaic structure that comprises a microcrystalline seed layer and single crystal nanowires, according to some embodiments, is a hetero-crystalline photovoltaic cell.

The material of the substrate includes, but is not limited to, a glass, a ceramic, a metal, a plastic, a polymer, a dielectric and a semiconductor. A substrate material useful for the various embodiments herein includes materials having either a non-single crystal structure or a single crystal structure, as defined above. In various embodiments, the substrate may be one of rigid, semi-rigid and flexible, depending on specific applications of the photovoltaic structure. In some embodiments, the substrate material may be chosen at least for its ability to withstand manufacturing temperatures. In some embodiments, the substrate material may be chosen at least for its applicability to roll-to-roll batch processing. For example, the substrate material may be stainless steel or an aluminum foil. Moreover, the substrate may exhibit one or more of the following characteristics: thermally conductive, electrically conductive, refractive, reflective, opaque, and optically transparent, depending on the embodiment of the photovoltaic structure or the solar cell.

Semiconductor materials useful to various embodiments of the present invention include, but are not limited to, semiconductors and compound semiconductors composed of elements from Group IV (e.g., Si, Ge, SiGe), compound semiconductors composed of elements from Group III and Group V (e.g., InGaAs), and compound semiconductors composed of elements from Group II and Group VI (e.g., ZnO). For example, the bramble of nanowires may comprise single crystal silicon (Si) or indium phosphide (InP), the substrate seed layer and the mesa seed layer may independently comprise one of silicon (Si), germanium (Ge) and gallium arsenide (GaAs) in either a microcrystalline structure or an amorphous structure, and the substrate may be glass or a metal sheet. In another example, the substrate seed layer and the mesa seed layer may independently comprise either a microcrystalline hydrogenated silicon (‘mc-Si:H’) or an amorphous hydrogenated silicon (‘a-Si:H’).

In some embodiments, concomitant with a choice of the semiconductor materials independently used in the photovoltaic structure and the solar cell is a respective energy band gap of the respective materials. In some embodiments, the energy band gap of the bramble of nanowires is different from the energy band gap of one or both of the seed layers. In some embodiments, the energy band gap of the substrate seed layer is different from the energy band gap of the mesa seed layer. In other embodiments, the energy band gaps of the substrate seed layer and the mesa seed layer are the same. Using materials with different energy band gaps makes the photovoltaic cell a heterostructure device.

Various insulator materials useful for the embodiments of the present invention include, but are not limited to, one or more of an oxide, a nitride and a carbide of any of the semiconductor materials listed above that is a dielectric or is electrically nonconductive. For example, the insulator island of the mesa may be a silicon oxide or a silicon nitride. In other embodiments, the insulator material may be one or more of an oxide, a nitride, and a carbide of a metal, such as titanium or gallium, for example, that is electrically nonconductive. In some embodiments, the insulator material includes, but is not limited to, a polymer that can withstand processing temperatures above about 100° C. For example, the polymer can withstand temperatures between about 100° C. about 400° C. For example, a polymer insulator material may be a polyimide. In some embodiments, the substrate comprises an insulator material.

Various electrode materials useful for the embodiments of the present invention include, but are not limited to, a semiconductor material, a metal, a conductive oxide and a conductive silicide, and combinations and alloys thereof, which inherently is electrically conductive, or is rendered electrically conductive. Moreover, the electrode material has one of an amorphous structure, a microcrystalline structure, a polycrystalline structure and a single crystal structure. In some embodiments, the substrate electrode and the mesa electrode are independently highly doped semiconductor materials from the list of semiconductor materials provided above. For example, the electrodes independently comprise a highly doped polycrystalline silicon or highly doped amorphous hydrogenated silicon (‘a-Si:H’). In some embodiments, the substrate is an electrically conductive material and functions as the substrate electrode.

In some embodiments, the electrode material is a metal that includes, but is not limited to, gold, silver, platinum, palladium, tin, aluminum, chromium, nickel and copper, and combinations and alloys thereof. For example, one or both of the substrate electrode and the mesa electrode may comprise a layer of titanium and a layer of platinum deposited on the titanium layer. In some embodiments, one or both of the electrodes is a silicide or a germanide that includes, but is not limited to, platinum silicide (PtSi) and titanium silicide (TiSi). A silicide-containing electrode may provide a low resistance interface (e.g., lower series resistance) that improves efficiency of the solar cell. Additional exemplary materials for the electrodes include, but are not limited to, indium-tin-oxide (ITO), zinc oxide (ZnO) and a highly doped polycrystalline silicon (i.e., ‘poly-Si’).

For simplicity herein, a ‘substrate surface’ may mean either a surface of a substrate or a seed layer of material on a surface of a substrate, depending on the embodiment of the present invention. The term ‘optically transparent’ is defined herein as being either transparent or semi-transparent to electromagnetic radiation in one or more of visible, UV and IR spectrums. The term ‘about’ means the values provided herein encompass normal material and process variations, for example. Further, as used herein, the article ‘a’ is intended to have its ordinary meaning in the patent arts, namely ‘one or more’. For example, ‘a nanowire’ generally means one or more nanowires and as such, ‘the nanowire’ means ‘the nanowire(s)’ herein. Also, any reference herein to ‘top’, ‘bottom’, ‘upper’, ‘lower’, ‘up’, ‘down’, ‘left’, ‘right’, ‘first’ or ‘second’ is not intended to be a limitation herein. Moreover, examples herein are intended to be illustrative only and are presented for discussion purposes and not by way of limitation.

The use of brackets ‘[ ]’ herein in conjunction with such numbers as ‘111’ and ‘110’ pertains to a direction or orientation of a crystal lattice and is intended to include a set of equivalent directions ‘< >’ within its scope, for simplicity herein. The use of parenthesis ‘( )’ herein with respect to such numbers as ‘111’ and ‘110’ pertains to a plane or a planar surface of a crystal lattice and is intended to include planes of equivalent symmetry ‘{ }’ within its scope for simplicity herein. Such uses are intended to follow common crystallographic nomenclature known in the art.

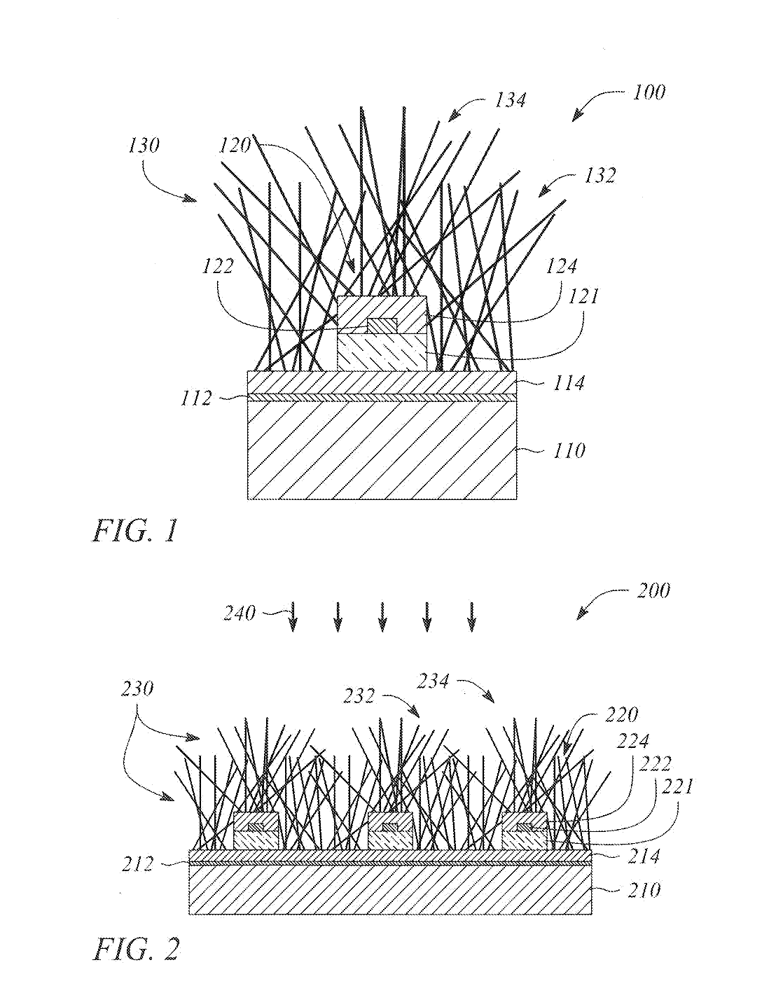

In some embodiments of the present invention, a photovoltaic structure with a hidden electrode is provided. FIG. 1 illustrates a cross sectional view of a photovoltaic structure 100, according to an embodiment of the present invention. The photovoltaic structure 100 comprises a mesa 120 on a substrate 110. The substrate 110 includes a layer 112 of a first electrode material on a surface of the substrate 110 and a layer 114 of a first seed material that covers the first electrode layer 112. The first seed layer 114 is an extrinsic semiconductor material, as defined above, comprising either a p-type dopant or an n-type dopant (not illustrated in FIG. 1). In some embodiments (not illustrated), the substrate is electrically conductive and functions as the first electrode and therefore, the first electrode layer 112 is eliminated.

The mesa 120 comprises an insulator island 121 on the first seed layer 114, a second electrode 122 on a surface of the insulator island 121, and a second seed layer 124 that covers the insulator island 121 surface and the second electrode 122, such that the second electrode 122 is buried under the second seed layer 124. The second seed layer 124 is also an extrinsic semiconductor material, as defined above, comprising the reverse or opposite dopant type (not illustrated in FIG. 1) relative to the first seed layer 114. The semiconductor material of the first seed layer 114 may be the same or different from the semiconductor material of the second seed layer 124.

The photovoltaic structure 100 further comprises a bramble 130 of nanowires 132, 134 that populates the surfaces of the second seed layer 124 of the mesa 120 and the first seed layer 114 of the substrate 110. One end of some of the nanowires 132 of the bramble 130 is anchored to the first seed layer 114 (herein referred to as ‘first nanowires 132’) and one end of others of the nanowires 134 of the bramble 130 is anchored to the second seed layer 124 (herein referred to as ‘second nanowires 134’ or the ‘mesa nanowires 134’). The nanowires 132, 134 further comprise a nanoparticle (not illustrated) at a tip of the nanowires. The tip is opposite to the end of the nanowires 132, 134 that is anchored to the respective seed layer 114, 124. The nanoparticle is a catalyst material that catalyzes nanowire growth, as described further below.

The disordered arrangement of the nanowires of the bramble 130 ensures that a first nanowire 132 that extends from the first seed layer 114 of the substrate 110 physically contacts a second nanowire 134 that extends from the second seed layer 124 on the mesa 120 of the photovoltaic structure 100. In some embodiments, the disordered arrangement facilitates a first nanowires 132 and a second nanowires 134 fusing together during growth. In some embodiments, the disordered arrangement of the nanowire of the bramble 130 further facilitates that a first nanowire 132 that extends from the first seed layer 114 directly physically contacts the second seed layer 124 of the photovoltaic structure 100. In some embodiments, the disordered arrangement of the nanowire bramble 130 further facilitates that a second nanowire 134 that extends from the second seed layer 124 directly physically contacts the first seed layer 114 of the photovoltaic structure 100. As such, one or more second nanowires 134 extend from a sidewall surface of the second seed layer 124 of the mesa 120 with a low-take off angle to contact the first seed layer 114. The nanowires 132, 134 that directly connect the two seed layers do so by a shorter path than the nanowires 132, 134 that physically connect together and therefore, are likely to contribute to a majority of photocurrent.

The photovoltaic structure 100 further comprises a semiconductor junction. The semiconductor junction comprises the bramble of nanowires 130 and the seed layers 114, 124. The first nanowire 132 on the first seed layer 114 and the second nanowire 134 on the second seed layer 124 that make physical contact to each other form a semiconductor junction. Moreover, those first and second nanowires 132, 134 that directly physically contact the other respective seed layer 114, 124 directly provide a semiconductor junction. In some embodiments, the bramble 130 of nanowires 132, 134 comprises an intrinsic semiconductor material, as defined above. In some embodiments, the entire axial length of the nanowires 132, 134 of the bramble 130 is an intrinsic semiconductor. In other embodiments, the first nanowires 132 and the second nanowires 134 of the bramble 130 independently may comprise an extrinsic semiconductor axial length segment (i.e., extrinsic region) directly adjacent to and the same dopant type as the respective seed layer 114, 124 to which they are anchored, and an intrinsic semiconductor axial segment (i.e., intrinsic region) adjacent to the respective extrinsic axial segment. In these embodiments, the intrinsic semiconductor axial segment of some of the first nanowires 132 and the second nanowires 134 one or both of physically contacts each other or physically contacts the respective other seed layer 114, 124.

In some embodiments, the entire axial length of one of the first nanowires 132 and the second nanowires 134 of the bramble 130 is an intrinsic semiconductor, while the other of the nanowires 132, 134 of the bramble 130 may comprise one or both of an axial segment of an intrinsic semiconductor and an axial segment of an extrinsic semiconductor. In still other embodiments, the entire axial length of one of the first nanowires 132 and the second nanowires 134 of the bramble 130 is an extrinsic semiconductor having the dopant type of the respective seed layer to which they are anchored, while the other of the nanowires 132, 134 of the bramble 130 may comprise one or both of an axial segment of an intrinsic semiconductor and an axial segment of an extrinsic semiconductor. Other combinations of doping the nanowires may be devised for forming semiconductor junctions in the photovoltaic structure and all such combinations are within the scope of the embodiments herein.

The seed layers 114, 124 independently comprise a semiconductor material capable of facilitating catalyzed growth of a single crystal nanowire from a surface of the seed layer. In some embodiments, the seed layers 114, 124 are independently microcrystalline semiconductor materials, as defined above. In some embodiments, one or both of the seed layers 114, 124 is an amorphous semiconductor material capable of facilitating catalyzed single crystal nanowire growth. By definition, microcrystalline semiconductor materials and amorphous semiconductor materials will facilitate growth of a bramble of nanowires, as illustrated in FIG. 1.

The first electrode 112 is hidden by the first seed layer 114 while the second electrode 122 is hidden by the second seed layer 124. An end of the first electrode 112 is electrically accessible for connection, while an end of the second electrode 122 is electrically accessible for connection (both accessible ends not illustrated in the cross sectional view of FIG. 1). However, the accessibility of the first electrode 112 and the second electrode 122 is external to and does not obstruct a photon path to the semiconductor junctions of the photovoltaic structure 100.

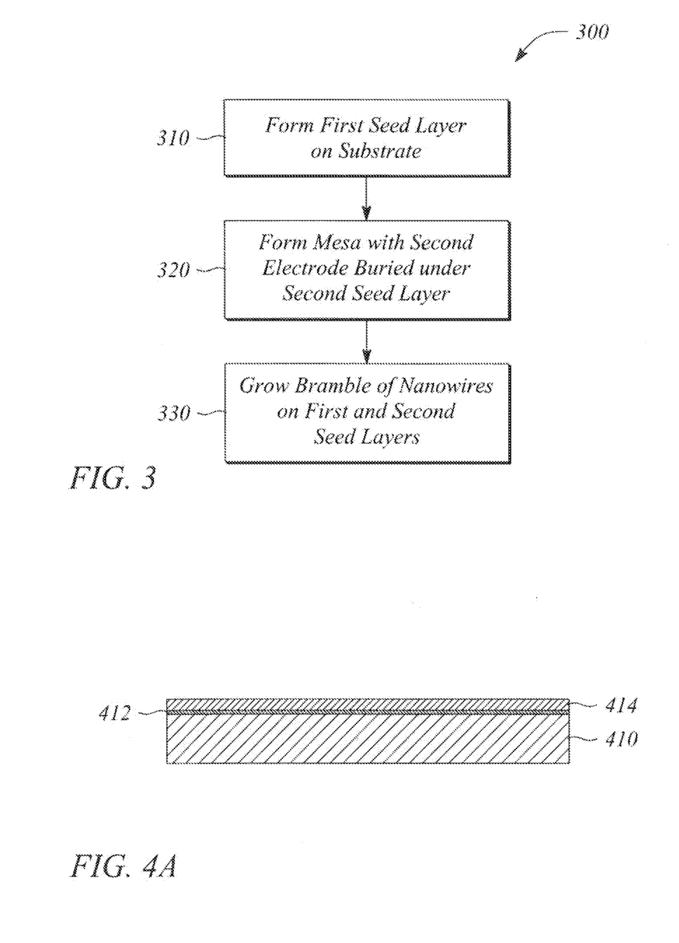

In some embodiments of the present invention, a solar cell having a hidden electrode is provided. FIG. 2 illustrates a cross sectional view of a solar cell 200 according to an embodiment of the present invention. The solar cell 200 comprises a first electrode 212 sandwiched between a substrate 210 and a first seed layer 214. In some embodiments, the first electrode 212 is a ‘substrate’ electrode 212 in that it extends as a continuous layer on the substrate 210. The first electrode 212 is accessible from an exposed end of the first electrode 212 external to a photon path 240 of the solar cell 200. In some embodiments (not illustrated), the substrate 210 is electrically conductive and functions as the first electrode 212 and therefore, a separate first electrode layer 212 may be eliminated.

The solar cell 200 further comprises a plurality of mesas 220 spaced apart from one another on the first seed layer 214. Only three mesas 220 are illustrated in FIG. 2 by way of example. Each mesa 220 comprises an insulator island 221 adjacent to the first seed layer 214; a second seed layer 224 on the insulator island 221; and a second electrode 222 buried between the second seed layer 224 and the insulator island 221. The second electrodes 222 are ‘mesa’ electrodes in that they are exclusive to their respective mesa 220. The second electrodes 222 are individually accessible from an exposed end of the second electrodes 222 external to the photon path 240 of the solar cell 200. The accessibility of the second electrodes 222 at their respective exposed ends facilitates electrical connection of the spaced apart mesas 220 to a common bus, for example.

The solar cell 200 further comprises a bramble 230 of nanowires. The bramble 230 comprises a plurality of first nanowires 232 having one end of each first nanowire 232 anchored to the first seed layer 214 and electrically accessible by the first electrode 212. The bramble 230 further comprises a plurality of second nanowires 234 having one end of each second nanowire 234 anchored to the second seed layer 224 of the respective mesas 220 and are electrically accessible by the respective second electrode 222. In accordance with the definition provided herein for ‘bramble,’ the first nanowires 232 and the second nanowires 234 are located on and extend in a variety of directions away from their respective seed layer 214, 224 in a disordered or chaotic fashion. Some of the first nanowires 232 extend from the first seed layer 214 in gaps between the plurality of mesas 220.

The solar cell 200 further comprises semiconductor junctions (not illustrated in FIG. 2) between the first electrode 212 hidden under the first seed layer 214 of the solar cell 200 and the second electrode 222 hidden under the second seed layer 224 of each mesa 220. The plurality of mesas 220 effectively shares the first electrode 212 of the solar cell 200. The semiconductor junctions comprise nanowires and the seed layers. The first seed layer 214 and the second seed layer 224 independently comprise an extrinsic semiconductor, as defined above, comprising opposite (or reverse) ones of a p-type dopant or an n-type dopant (not illustrated in FIG. 2). In some embodiments, the first nanowires 232 and the second nanowires 234 independently comprise an intrinsic semiconductor. In some embodiments, the first nanowires 232 and the second nanowires 234 comprise the same intrinsic semiconductor. The semiconductor junctions of the solar cell 200 comprise some of the first nanowires 232 and some of the second nanowires 234 being in physical contact with each other. In some embodiments, the semiconductor junctions further comprise some of the first nanowires 232 being in direct physical contact with the second seed layer 224. In some embodiments, the semiconductor junctions further comprise some of the second nanowires 234 being in direct physical contact with the first seed layer 214. In some embodiments, the semiconductor junctions are p-i-n junctions.

In some embodiments, the solar cell 200 may further comprise an optically transparent coating (not illustrated) on the bramble 230 of nanowires. The optically transparent coating maintains an uneven surface of the solar cell 200 formed by the bramble 230. The uneven surface of the solar cell 200 is a photon receiving surface adjacent to the photon path 240. In some embodiments, the optically transparent coating is a layer of an optically transparent material that covers most or all of the outermost tips of the nanowires (for example, similar to a layer of snow on a bush). In some embodiments, the optically transparent coating conformally covers most or all of the axial length of the outermost nanowires; for example, the optically transparent coating follows the contours of the bramble 230 and extends further into the bramble than the optically transparent layer, described above. In other embodiments, the optically transparent coating embeds the bramble 230 of nanowires. In some of these embodiments, the optically transparent coating extends approximately from the surface of the first seed layer 214, embeds the mesas 220 and includes some of the outermost tips of the nanowires 232, 234. In some of these embodiments, the embedded bramble 230 of nanowires maintains the uneven surface of the solar cell 200.

In some embodiments, the solar cell 200 further comprises an optically transparent enclosure (not illustrated) that protects at least the bramble 230 of nanowires. In some embodiments, the optically transparent enclosure comprises a transparent housing that protects the above-described elements of the solar cell 200 from contaminants in an environment in which the solar cell 200 is used. In these embodiments, the optically transparent housing further provides for cleaning contaminants from external surfaces of the solar cell 200, especially contaminants that might obstruct the photon path 240 of the solar cell 200. In some embodiments, the optically transparent enclosure further comprises the transparent coating on the bramble 230 of nanowires, as described above.

The figures herein illustrate cross-sectional views of mesa structures 120, 220 on substrates 110, 210. From a perspective view (not illustrated), the plurality of mesas of the solar cell may be arranged or electrically connected one or both of 2-dimensionally or 3-dimensionally. For example, the plurality of mesas 220 may be arranged as spaced apart, relatively parallel fingers on the substrate 210. In another example, the plurality of mesas 120 may be arranged in a grid pattern on the substrate 210. In some embodiments, the mesas 220 of the solar cell 200 are the same as the mesa 120 of the photovoltaic structure 100 described above. In some embodiments, the solar cell 200 comprises a plurality of the photovoltaic structures 100, described above, wherein the photovoltaic structures are electrically connected together. For example, the substrate electrodes (first electrode 112, 110) may be electrically connected together via a first common bus; and the mesa electrodes (second electrode 122) of the respective photovoltaic structures 100 may be electrically connected to a second common bus to form the solar cell 200 in some embodiments.

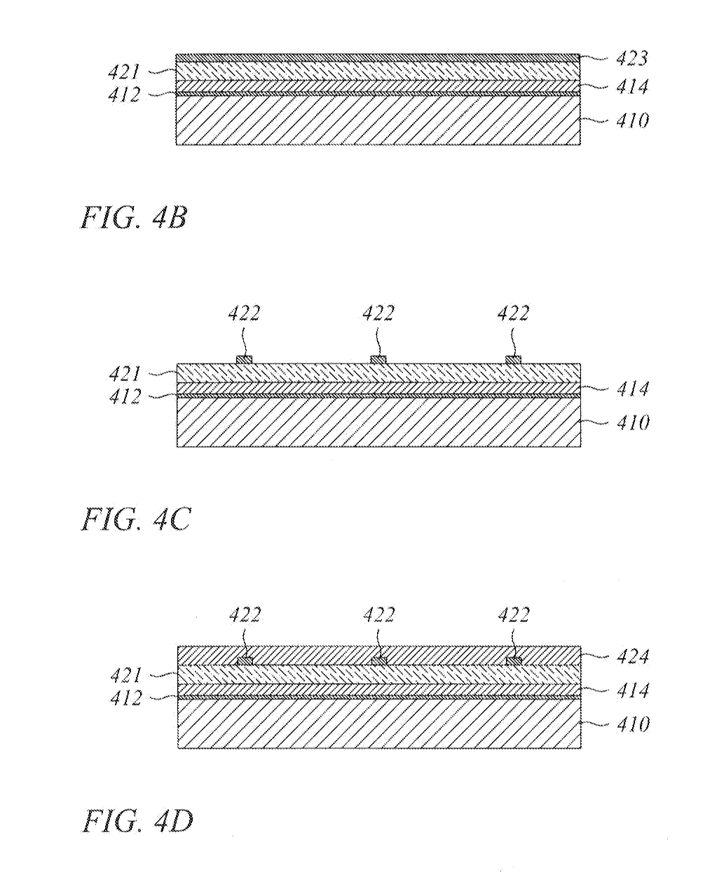

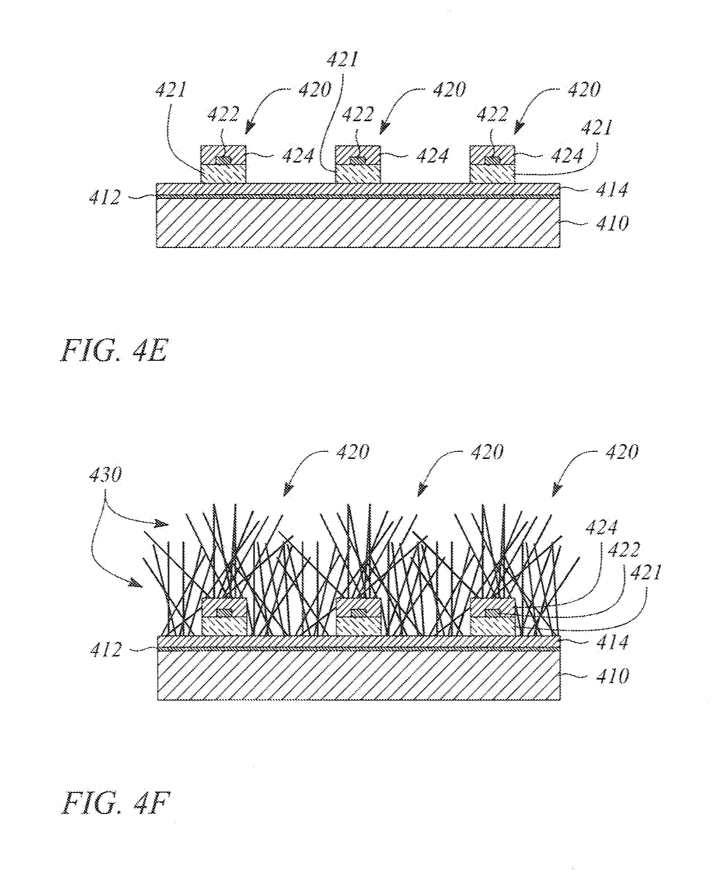

In another embodiment of the present invention, a method of fabricating a solar cell with a hidden electrode is provided. The method of fabricating a solar cell includes within its scope fabricating a photovoltaic structure. FIG. 3 illustrates a flow chart of a method 300 of fabricating a solar cell according to an embodiment of the present invention. FIGS. 4A-4F illustrate cross sectional views of a solar cell during fabrication according to an embodiment of the present invention.

Referring to FIG. 3, the method 300 of fabricating a solar cell comprises forming 310 a first seed layer on a substrate that comprises a first electrode. In some embodiments, the substrate comprises a non-single crystal material, as defined above. In some embodiments, the substrate is electrically conductive and the substrate is the first electrode. In other embodiments, the substrate comprises a first electrode layer on which the first seed layer is formed 310. The first seed layer comprises an extrinsic semiconductor material having a first dopant type, as defined above. The first electrode layer comprises an electrically conductive material, as provided above. In some embodiments, the first electrode layer comprises a metal adhesion layer on the substrate surface, followed by a metal surface layer. The metal adhesion layer facilitates adhesion between the substrate and the metal surface layer. For example, the first electrode layer may comprise a titanium adhesion layer and a platinum surface layer. The titanium adhesion layer facilitates adhesion of the platinum surface layer to the substrate. In another example, the first electrode layer may comprise a chromium adhesion layer and the surface layer may be nickel. The chromium adhesion layer facilitates adhesion between the substrate and the nickel surface layer of the first electrode.

The first electrode layer is deposited using any of a variety of techniques including, but not limited to, electroplating, e-beam evaporation and sputtering. The first seed layer is formed 310 on the first electrode layer using a deposition technique including, but not limited to, various types of chemical vapor deposition (CVD) for example plasma enhanced CVD (PECVD). FIG. 4A illustrates a cross sectional view of a substrate 410 having a first electrode layer 412 on the substrate 410 that is covered with a first seed layer 414 according to an embodiment of the present invention.

The method 300 of fabricating a solar cell further comprises forming 320 a mesa on the first seed layer. The mesa comprises an insulator material island, a second electrode, and a second seed layer (and may be referred to herein as a ‘photovoltaic mesa’). The insulator material island is adjacent to and surrounded by the first seed layer on two or more sides, for example. The second electrode is buried under the second seed layer on the insulator island. The second seed layer covers both the second electrode and the horizontal surface of the insulator island. The insulator material island may be any of the insulator materials provided above. The second seed layer comprises an extrinsic semiconductor material, as defined above, having a second dopant type that is the reverse (opposite) of the first dopant type of the first seed layer. The second electrode may comprise any of the electrode materials provided above.

The method 300 of fabricating a solar cell further comprises growing 330 a bramble of nanowires on surfaces of the first seed layer and the second seed layer. Some nanowires of the first seed layer and some nanowires of the second seed layer make physical contact with each other during growth 330. In some embodiments, some nanowires of the first seed layer make physical contact with the second seed layer during growth 330. In some embodiments, some nanowires of the second seed layer make physical contact with the first seed layer during growth 330. The nanowires comprise one or both of an intrinsic semiconductor and an extrinsic semiconductor. The physically contacting nanowires from the separate seed layers form semiconductor junctions. Moreover, some nanowires of the first seed layer physically contacting the second seed layer form semiconductor junctions.

The type of semiconductor junction depends in part on the make-up of the nanowires. In some embodiments, the nanowires are intrinsic semiconductors, as defined herein. For example, the volume of the nanowire is an intrinsic region. In this embodiment, the semiconductor junctions are p-i-n junctions. In other embodiments, the nanowires comprise an intrinsic semiconductor and an extrinsic semiconductor. For example, the nanowires have an intrinsic semiconductor region in an axial segment and an extrinsic semiconductor region in an adjacent axial segment. In these embodiments, the semiconductor junctions comprise p-i-n junctions and may further comprise p-n junctions, depending on where the nanowires physically contact each other, for example. in some embodiments, the nanowires arc extrinsic semiconductors, in that the volume of the nanowires is an extrinsic region, wherein the respective dopant type of the extrinsic region is the same as the dopant type of the seed layer from which the nanowires are anchored. In these embodiments, the semiconductor junctions are p-n junctions.

In some embodiments, growing 330 a bramble of nanowires comprises growing the nanowires anchored to the first seed layer at the same time as growing the nanowires anchored to the second seed layer. In these embodiments, the nanowires comprise an intrinsic semiconductor, such that the volume of the nanowires is an intrinsic region. Moreover, the intrinsic semiconductor material of the nanowires is the same for all nanowires of the bramble. In these embodiments, the semiconductor junctions formed between the nanowires and the first seed layer and the second seed layer are p-i-n junctions. Moreover, some nanowires fuse together when they make physical contact during growth 330; and some nanowires fuse to the other seed layer when they make physical contact with the other seed layer during growth 330.

In some embodiments, growing 330 a bramble of nanowires comprises growing the nanowires anchored to the first seed layer separately from growing the nanowires anchored to the second seed layer. In these embodiments, the nanowires grown anchored to the first seed layer may be a different semiconductor material and may comprise a different doping profile from the nanowires separately grown anchored to the second seed layer. In these embodiments, the semiconductor junctions may comprise both p-n junctions and p-i-n junctions, depending on the doping profiles and where the nanowires from the first and second seed layers make physical contact. In some embodiments, the nanowires have any of the doping profiles discussed above. Separately growing 330 nanowires from the respective seed layer may comprise masking the surfaces of the seed layer from which nanowire growth is not targeted while growing the nanowires from the targeted seed layer. The mask material may be removed to grow nanowires on the remaining seed layer surfaces.

In some embodiments, forming 320 a photovoltaic mesa comprises depositing an insulator layer on the first seed layer and depositing a second electrode layer on the insulator layer. FIG. 4B illustrates a cross sectional view of the substrate 410 of FIG. 4A further comprising an insulator layer 421 on the first seed layer 414 and a second electrode layer 423 on the insulator layer 421 according to an embodiment of the present invention. In some embodiments, the various layers blanket the substrate 410. The insulator layer 421 may be deposited using a variety of deposition techniques including, but not limited to, PECVD. The second electrode layer 423 may be deposited in much the same way as described above for the first electrode layer.

In some embodiments, forming 320 a photovoltaic mesa further comprises patterning the second electrode layer into spaced apart electrode elements with exposed portions of the insulator layer between the second electrode elements. FIG. 4C illustrates a cross sectional view of the spaced apart second electrode elements 422 patterned from the second electrode layer 423 according to an embodiment of the present invention. The second electrode layer may be patterned using a variety of methods. For example, the second electrode layer may be patterned using one or more of stamping, photolithography and nanoimprint lithography that may be followed by one or both of wet etching and dry etching.

In another example, the second electrode layer may be patterned using photolithography and a lift-off process. In this example, a photoresist is applied to the insulator layer before the second electrode layer is deposited. The photoresist is patterned into spaced apart segments with the insulator layer exposed between the segments, for example. Then the second electrode layer is deposited on the exposed insulator layer and on the patterned photoresist segments. To create the spaced apart second electrode elements, the patterned photoresist segments are removed using known techniques and the second electrode material deposited on the patterned photoresist segments is lifted-off with the photoresist. The spaced apart second electrodes remain on the insulator layer.

In some embodiments, forming 320 a mesa further comprises depositing a second seed layer to coat the second electrode elements and the exposed portions of the insulator layer. FIG. 4D illustrates a cross sectional view of the substrate 410 of FIG. 4C further including the second seed layer 424 deposited on the insulator layer 421 and the second electrode elements 422 according to an embodiment of the present invention.

In some embodiments, forming 320 a mesa further comprises removing sections of the insulator layer and the overlying second seed layer between the second electrode elements to expose the first seed layer underneath, such that isolated mesas remain with second electrode elements buried or hidden by the second seed layer. FIG. 4E illustrates a cross sectional view of the substrate 410 of FIG. 4D with mesas 420 spaced apart on the surface of the first seed layer 414 by gaps according to an embodiment of the present invention. The first seed layer 414 is exposed in the gaps between the mesas 420. The first seed layer 414 surrounds the mesas 420 on two sides, for example. FIG. 4E illustrates three such mesas 420 by way of example only.

In some embodiments, the sections of the insulator layer and overlying seed layer are removed using either photolithography and etching or nano-imprint lithography and etching. The etching may be one or both of dry etching, such as reactive ion etching (RIE), and wet chemical etching. When the substrate 410 is relatively flexible, the fabrication of the solar cell up to this point may be performed using a roll-to-roll system.

According to some embodiments of the method 300 of fabricating a solar cell, one or more of the dimensions of the mesas and the various material layers, spacing of the mesas and the nanowire length are dependent on the material characteristics of the nanowires, for example. Material characteristics including, but not limited to, the lifetime of carriers, the quality of the material and the passivation, for example, may dictate what the spacing may be used between mesas. For example, the longer the carrier lifetime of the nanowire material then the longer the nanowire can be and the further apart the mesas may be spaced.

For example, single crystal silicon nanowires have a relatively longer carrier lifetime than some other semiconductor materials, and non-single crystal silicon materials (e.g., amorphous silicon) and therefore, single crystal silicon nanowires can be longer in axial length than a semiconductor material having a shorter carrier lifetime. In an example of using silicon nanowires that are about 4 microns long, the second electrode elements may be from about 0.5 micron to about 5 microns in width and from about 100 nanometers (nm) to about 1 micron thick. The insulator island may be about 100 nm to about 300 nm thick and the second seed layer may be about 100 nm to about 500 nm thick, for example. The first seed layer may about 100 nm to about 1 micron thick, for example. Moreover, the photovoltaic mesa may be about 1 micron to about 10 microns wide and the gaps between mesas may be about 1 micron to about 5 microns, in this example. However, when silicon nanowires that are about 20 microns long, for example, are used, a larger design space is provided to such dimensions as the mesa spacing and the thickness of various layers, for example, than the example above using silicon nanowires that are about 4 microns long.

In some embodiments, the mesa has a relatively long and narrow aspect ratio, such as a finger or bar, for example, extending from opposite ends of the substrate. In these embodiments, the first seed layer on the substrate surrounds the mesa on two long sides. The second electrode on the mesa runs the length of the mesa and is accessible on one or both of the two short sides (ends) of the mesa.

According to some embodiments of the method 300 of fabricating a solar cell, growing 330 a bramble of nanowires comprises forming a nanoparticle catalyst on the surfaces of the first seed layer and the second seed layer. For example, the nanoparticle catalyst is formed on the first seed layer surrounding or adjacent to the mesas. Moreover, the nanoparticle catalyst is formed on the second seed layer of the mesas, for example on both exposed vertical surfaces and horizontal surfaces of the second seed layer of the mesas relative to a main plane of the solar cell substrate. Nanoparticles may be applied in a variety of ways to the surfaces.

For example, nanoparticles may be dispersed in a liquid solvent that is applied to the surfaces, such as by a spin coating technique. The liquid solvent is evaporated such that the nanoparticles remain on the surfaces in random locations. In another example, nanoparticles are deposited on the surfaces in a thin film, such as by using a spray coating technique, and then the thin film is annealed to create discontinuities between the nanoparticles. In these examples, the nanoparticles are in a solid, powder form and their application provides a disordered distribution of nanoparticles on the surfaces of the respective seed layer. For example, the nanoparticles may be a colloidal suspension of gold (Au) particles in a toluene solvent. In another example, the nanoparticles may be applied using electrochemical deposition. Electrochemical deposition may offer selectivity in terms of locations on a surface where the nanoparticle deposition takes place. The nanoparticle catalysts formed on the respective seed layer surfaces nucleate growth of nanowires from the respective seed layer surface to populate the seed layers. The nanoparticle catalyst comprises a metal including, but not limited to, titanium (Ti), platinum (Pt), nickel (Ni), gold (Au), gallium (Ga), and combinations and alloys thereof.

After the nanoparticle catalysts are formed on the respective seed layer surfaces, nanowires are nucleated by the nanoparticle catalysts to grow 330 in a variety of directions from the respective seed layer surface based on a crystal orientation or direction of the respective crystallites in the seed layer surface at the nanoparticle catalyst location. Growing 330 the bramble of nanowires comprises using a catalytic growth process, for example a vapor-liquid-solid (VLS) epitaxial growth using the nanoparticle as a catalyst. In some embodiments, a combination of catalytic growth and non-catalytic growth are used to manipulate a shape of the nanowire along its axial length. In some embodiments, nanowire growth is initiated in a CVD reaction chamber using a gas mixture of a nanowire source material that is introduced into the chamber at a growth temperature and using the nanoparticle catalyst. For example, indium phosphide (InP) nanowires may be grown using metal organic CVD (MOCVD). In this example, trimethylindium and phosphine in a hydrogen carrier gas may be used with a gold nanoparticle catalyst. The InP nanowires are anchored to the respective seed layer and have metallic tips comprising gold in this example.

Due to the disorder of the nanowire growth directions, the nanowires of the bramble extend in a variety of directions. For example, some nanowires on the same seed layer may fuse with each other at some point during growth. Moreover, one or more of some nanowires of the first seed layer and of the second seed layer will fuse together during growth; some nanowires of the first seed layer will fuse with the second seed layer during growth; and some nanowires of the second seed layer will fuse with the first seed layer during growth, according to some embodiments of the present invention. In some embodiments, some nanowires will make physical contact, but may not fuse with other nanowires.

In some embodiments, the method 300 of fabricating a solar cell further comprises applying an optically transparent coating to at least the bramble of nanowires. The optically transparent coating may be applied using a variety of techniques including, but not limited to, PECVD and spray coating, for example. Moreover, the fabricated solar cell may be further or alternately enclosed in an optically transparent housing that protects the elements of the solar cell from the environment in which the solar cell is placed, according to some embodiments of the method 300. For example, the optically transparent housing may provide a hermetic seal to protect the solar cell. A variety of materials including, but not limited to, glass, silicon dioxide, silicon nitride and polymeric materials that are optically transparent, may be used to protect the solar cell and in some embodiments, to hermetically seal the solar cell. In some embodiments, the optically transparent housing or enclosure is rigid or semi-rigid. In other embodiments, the optically transparent housing or enclosure is relatively flexible. In some embodiments, the method 300 of fabricating a solar cell is used to fabricate any of the embodiments of the solar cell 200, described above. In some embodiments, the method 300 of fabricating a solar cell is used to fabricate any of the embodiments of the photovoltaic structure 100, described above. In some embodiments, the method 300 of fabricating a solar cell provides a plurality of interconnected photovoltaic structures 100.

Thus, there have been described embodiments of a photovoltaic structure, a solar cell and a method of fabricating a solar cell that employ hidden electrodes. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A photovoltaic structure (100) with a hidden electrode (122) comprising:
a mesa (120) on a substrate (110), the mesa (120) comprising:
an insulator island (121) adjacent to a surface of the substrate (110); and
an electrode (122) buried under a seed layer (124) on the insulator island (121);
a bramble (130) of nanowires (132, 134), one end of some of the nanowires (134) of the bramble (130) being anchored to the seed layer (124) of the mesa (120), one end of others of the nanowires (134) of the bramble (130) being anchored to a seed layer (114) on the substrate (110) adjacent to the mesa (120), the seed layers (114, 124) independently being an extrinsic semiconductor; and
a semiconductor junction comprising the seed layers (114, 124) and some of the nanowires (132, 134) of the bramble (130).

2. The photovoltaic structure (100) of claim 1, wherein the nanowires (132, 134) of the bramble (130) comprise an intrinsic semiconductor, a nanowire (132) anchored to the seed layer (114) on the substrate (110) being in physical contact with a nanowire (134) anchored to the seed layer (124) on the mesa (120), the semiconductor junction comprising a p-i-n junction.

3. The photovoltaic structure (100) of claim 1, wherein a photon path to the semiconductor junction is unobstructed by the buried electrode (122) of the mesa (120), a respective end of the buried electrode (122) of the mesa (120) being physically and electrically accessible external to a photon path of the photovoltaic structure (100).

4. The photovoltaic structure (100) of claim 1, wherein one or both of the seed layers (114, 124) is a microcrystalline semiconductor material.

5. The photovoltaic structure (100) of claim 1, further comprising an optically transparent coating on the bramble (130) of nanowires (132, 134).

6. A solar cell (200) comprising a plurality of the photovoltaic structures (100) of claim 1 electrically connected together.

7. A solar cell (200) with a hidden electrode (222) comprising:
a first electrode (212, 210) buried under a first seed layer (214) on a substrate (210);
a plurality of mesas (220) spaced apart on the first seed layer (214), each mesa (220) comprising:
an insulator island (221) adjacent to the first seed layer (214); and
a second electrode (222) buried under a second seed layer (224) on the insulator island (221);
a bramble (230) of first nanowires (232) and second nanowires (234), one end of the first nanowires (232) being anchored to the first seed layer (214), one end of the second nanowires (234) being anchored to the second seed layer (224), the first nanowires (232) being in gaps between the spaced apart mesas (220), the seed layers (214, 224) independently being an extrinsic semiconductor; and
semiconductor junctions comprising some first nanowires (232) and some second nanowires (234) being in physical contact, wherein a photon path (240) to the semiconductor junctions is unobstructed by the buried second electrodes (222).

8. The solar cell (200) of claim 7, wherein the first seed layer (214) and the second seed layer (224) independently are a microcrystalline structure, the first nanowires (232) and the second nanowires (234) being an intrinsic semiconductor, the semiconductor junctions further comprising one or both of a first nanowire (232) being in physical contact with the second seed layer (224) and a second nanowire (234) being in physical contact with the first seed layer (214), the semiconductor junctions being p-i-n junctions.

9. The solar cell (200) of claim 7, further comprising an optically transparent enclosure that protects at least the bramble (230) of nanowires (232, 234).

10. The solar cell (200) of claim 7, wherein individual mesas (220) of the plurality are separately electrically accessible from an exposed end of respective buried second electrodes (222) and an exposed end of the buried first electrode (212, 210) that is shared among the plurality of mesas (220).

11. A method (300) of fabricating a solar cell (100, 200) with a hidden electrode comprising:
forming (310) a layer (414) of a first seed material comprising a first dopant type on a substrate (410) that comprises a first electrode (412, 410);
forming (320) a mesa (420) on the first seed layer (414), the mesa (420) comprising a second electrode (422) buried under a layer (424) of a second seed material on an insulator island (421) adjacent to the first seed layer (414), the second seed layer (424) comprising a second dopant type; and
growing (330) a bramble (430) of nanowires on surfaces of the first seed layer (414) and the second seed layer (424), nanowires on the first seed layer (414) and nanowires on the second seed layer (424) physically contacting one or both of each other and an opposite one of the seed layers (414, 424) to form semiconductor junctions.

12. The method (300) of fabricating the solar cell (200) of claim 11, wherein forming (310) a mesa comprises:
depositing an insulator layer (421) on the first seed layer (414);
depositing a second electrode layer (423) on the insulator layer;
patterning the second electrode layer (423) into spaced apart electrodes (422) of the second electrode layer (423) with exposed portions of the insulator layer (421) between the second electrodes (422);
depositing a second seed layer (424) to coat the second electrodes (422) and the exposed portions of the insulator layer (421); and
removing sections of the insulator layer (421) and the overlying second seed layer (424) between the second electrodes (422) to expose the first seed layer (414) underneath, wherein the isolated insulator islands (421) remaining after removing the sections form the mesas (420).

13. The method (300) of fabricating a solar cell (100, 200) of claim 11, wherein growing (330) a bramble (430) of nanowires comprises:
forming nanoparticle catalysts on surfaces of both the first seed layer (414) surrounding the mesa (420) and the second seed layer (424), the first seed material and the second seed material independently being a microcrystalline semiconductor; and
using the nanoparticle catalysts on the surfaces to nucleate nanowire growth (330), the nanowires of the bramble (430) being anchored at one end to the respective seed layer (414, 424) surfaces, the bramble (430) populating the surfaces.

14. The method (300) of fabricating a solar cell (100, 200) of claim 11, wherein the nanowires of the bramble (430) comprise an intrinsic region, the semiconductor junction comprising a p-i-n junction.

15. The method (300) of fabricating a solar cell (100, 200) of claim 11, further comprising protecting the solar cell (100, 200) with an optically transparent enclosure.
